(19) United States
(12) Patent Application Publication
(10) Pub. No.: US 2012/0264279 A1
(43) Pub. Date: Oct. 18, 2012

(54) METHOD FOR FABRICATING SEMICONDUCTOR DEVICE

(75) Inventors: Shui-Yen LU, Hsinchu County (TW); Yi-Po Lin, Tainan City (TW); Jiunn-Hsiung Liao, Tainan County (TW); Shih-Fang Tzou, Hsinchu County (TW); Shin-Chin Chen, Tainan County (TW)

(73) Assignee: UNITED MICROELECTRONICS CORP., Hsinchu (TW)

(21) Appl. No.: 13/085,787

(22) Filed: Apr. 13, 2011

(51) Int. Cl. H01L 21/28

(52) U.S. Cl. 438/585; 257/E21.158

(57) ABSTRACT

A method for fabricating a semiconductor device, wherein the method comprises steps as follows: a semiconductor structure comprising a substrate, a dummy gate structure having a dielectric layer disposed over the substrate and a silicon layer disposed over the dielectric layer, and an etching stop layer (ESL) and an inter-layer dielectric (ILD) layer both of which are sequentially disposed over the substrate and the dummy gate structure is first provided. Then, a chemical mechanical polishing (CMP) is performed to planrizing the ILD layer and expose the ESL. Subsequently, an in-situ etching process is conducted to remove portions of the ESL and the silicon layer to form an opening in the dummy gate structure. Next, metal material is filled into the opening.

### FIELD OF THE INVENTION

The present invention relates to a method for fabricating a semiconductor device, more particularly to a method for manufacturing a field effect transistor (FET) with a metal gate structure.

### BACKGROUND OF THE INVENTION

With the development of the electrical technology, a FET with high integrity and operation speed is required. As each technology nodes shrink, the dimensions of a FET and the thickness of its gate oxide, however, must be reduced and gate leakage could be more likely triggered by the reduced gate length.

In order to reduce gate leakage, high dielectric constant (high-k) gate insulator layers are used and the conventional polysilicon gate electrode is replaced with a metal gate (MG) electrode to improve the device performance as the feature sizes has being decreased.

However, there are still problems with the current fabrication approach of the high-k metal gate structure, thus to increase the yield of the FET is still a challenge to the industry. Therefore, it is necessary to provide an improved method for fabricating a FET with a high-k/metal gate structure to increase the yield thereof.

### SUMMARY OF THE INVENTION

One aspect of the present invention is to provide a method for fabricating a semiconductor device, wherein the method comprises steps as follows: a semiconductor structure comprising a substrate, a dummy gate structure having a dielectric layer disposed over the substrate and a silicon layer disposed over the dielectric layer, and an etching stop layer (ESL) and an ILD layer both of which are sequentially disposed over the substrate and the dummy gate structure is first provided. Then, a chemical mechanical polishing CMP is performed to planrizing the ILD layer and expose the ESL. Subsequently, an in-situ etching process is conducted to remove portions of the ESL and the silicon layer to form an opening in the dummy gate structure. Next, metal material is filled into the opening.

In one embodiment of the present invention, the ESL comprises silicon nitride or silicon oxynitride.

In one embodiment of the present invention, the in-situ etching process comprises a first dry etching step for removing a portion of the ESL in order to expose the silicon layer; a second dry etching step for removing the silicon layer; and a wet chemical treatment for removing the remaining the silicon layer.

In one embodiment of the present invention, the first dry etching step is a carbon fluoride (CF₄)/nitrogen (N₂) based dry etch. In one embodiment of the present invention, the first dry etching step has an etching selectivity of 1:1 for removing the ESL and the silicon layer. In one embodiment of the present invention, the second dry etching step is a chlorine (Cl₂) based dry etching. In one embodiment of the present invention, the second dry etching step partially removes a portion of the silicon layer so as to remain a portion of the silicon layer. In one embodiment of the present invention, the second dry etching step removes about 60% of the silicon layer.

In one embodiment of the present invention, the method further comprises a wet chemical treatment for removing the remaining silicon layer after the second dry etching step is conducted. In one embodiment of the present invention the wet chemical treatment is a wet etching step utilizing an etchant comprising tetramethylammonium hydroxide (TMAH) or ammonia (NH₃). In one embodiment of the present invention the method further comprises a step of forming a capping layer on the dielectric layer prior the silicon layer is formed, wherein the capping layer is a titanium nitride (TiN) layer and the second dry etching step has an etching rate for removing the silicon layer greater 10 times than that for removing the capping layer.

In one embodiment of the present invention, the second dry etching step is a hydrogen bromide (HBr) based dry etching. In one embodiment of the present invention, the wet chemical treatment is a cleaning step utilizing a reagent comprising TMAH.

In accordance with the aforementioned embodiments of the present invention, a method for fabricating a semiconductor device with a MG structure is provided, wherein a dummy poly gate previously formed on a semiconductor substrate is replaced by the metal gate structure. In stead of performing a conventional dummy poly gate removing procedure which includes a CMP process for removing a ESL covered on the dummy poly gate structure and a subsequent chemical wet etching process for removing a silicon layer of the dummy poly gate, an in-situ etching process is performed to accomplish the work done by the conventional dummy poly gate removing procedure at a time in the same processing chamber or cluster tool. Besides, in comparison with the traditional chemical wet etching process, the present in-situ etching process has lower etching selectivity for removing the silicon nitride and the silicon, thus the polymer residue generated in the etching process can be significantly reduced, so that the total account of the defect semiconductor device can also be reduced. Therefore, the drawbacks and problems encountered from the prior art can be solved.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A to 1D illustrate cross sectional views of the processing structures for fabricating a conventional high-k/metal gate structure of a FET.

FIGS. 2A to 2G illustrate cross sectional views of the processing structures for fabricating a high-k/metal gate FET in accordance with one embodiment of the present invention.

FIGS. 3A to 3B illustrate cross sectional views of the processing structure for fabricating a high-k/metal gate FET in accordance with another embodiment of the present invention.

### DETAILED DESCRIPTION OF PREFERRED EMBODIMENTS

One object of the present invention is to provide a method for fabricating a semiconductor device to increase the yield of a FET with a high-k/metal gate structure.

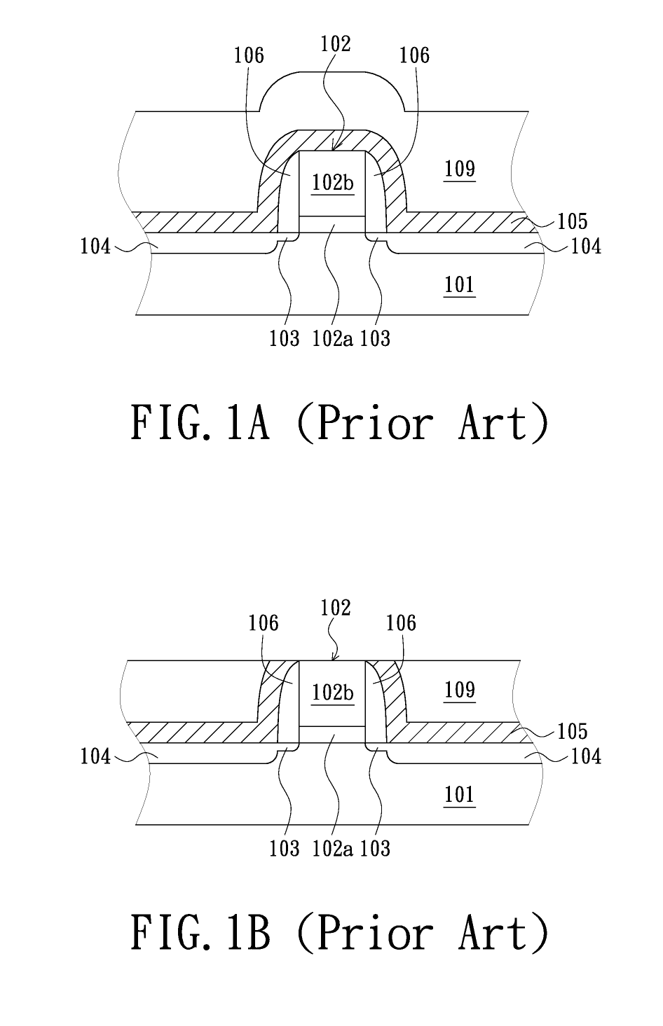

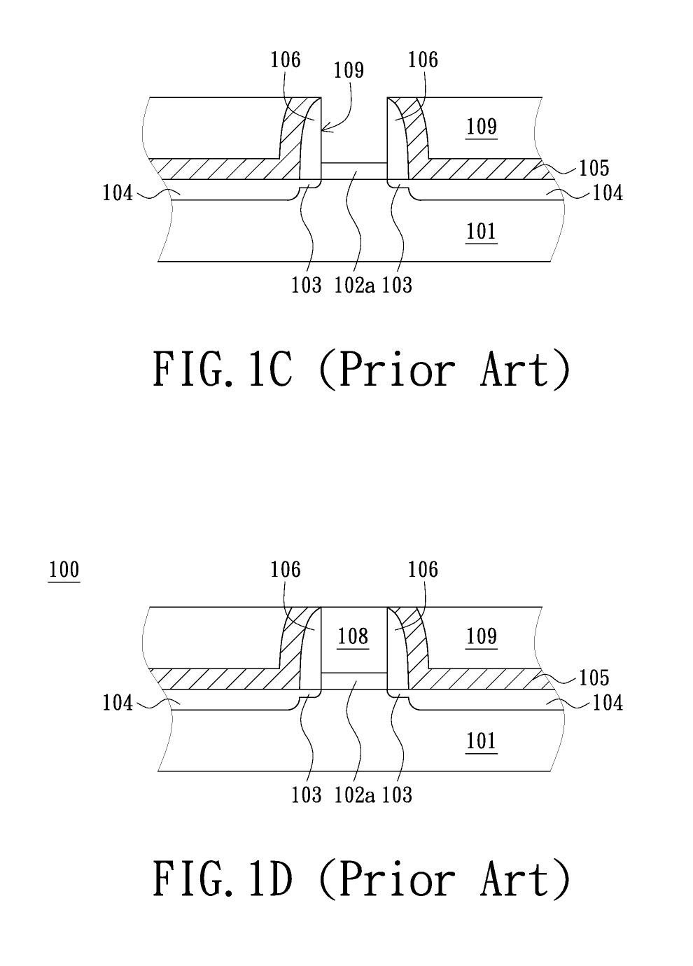

FIGS. 1A to 1D illustrate cross sectional views of the processing structures for fabricating a conventional high-k metal gate structure of a Field Effect Transistor (FET) 100. As shown in FIG. 1A, a dummy poly gate structure 102 comprising a gate dielectric layer 102a, a polysilicon gate electrode 102b and spacers 106 is formed over an active region of a substrate 101 in which lightly doped regions 103 and source/drain regions 104 are subsequently formed. Then, a contact etching stop layer (CESL) 105 and an interlayer dielectric (ILD) layer 109 are formed over the substrate 101 and the dummy poly gate structure 102.

Next, a chemical machine polish (CMP) process is conducted to planarize the CESL 105 and/or the ILD layer 109 until a top portion of the dummy poly gate structure 102 is exposed as shown in FIG. 1B. Subsequently, the polysilicon gate electrode 102b is removed by a dry or wet etching process to form an opening 107 surrounded by the remaining CESL 105 and/or the ILD layer 109 (shown in FIG. 1C), and a metal deposition process is then conducted to form a MG 108 so as to fill the opening 107 and substitute the removed polysilicon gate electrode 102b (shown in FIG. 1D).

However, since the post CMP etching process has a high selectivity for removing the polysilicon gate electrode 102b and the CESL 105, thus polymer residents may be generated and reside on the sidewalls of the opening 107 more easily, and cause the high-k/metal gate structure of the FET 100 defect.

Therefore, it is necessary to provide an improved method for fabricating a FET with a high-k/metal gate structure to obviate the drawbacks and problems encountered from the prior art.

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

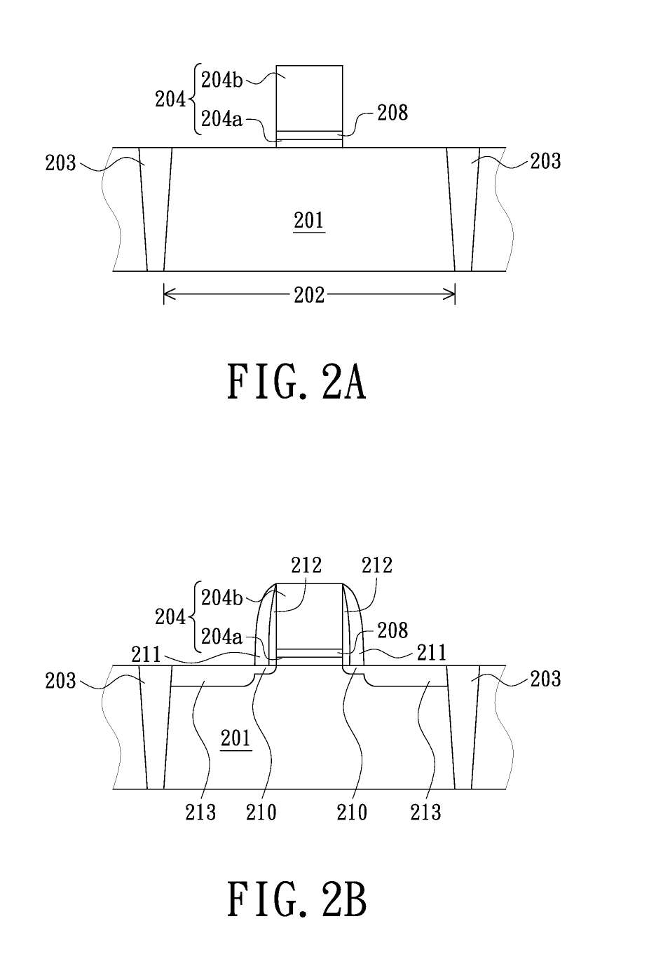

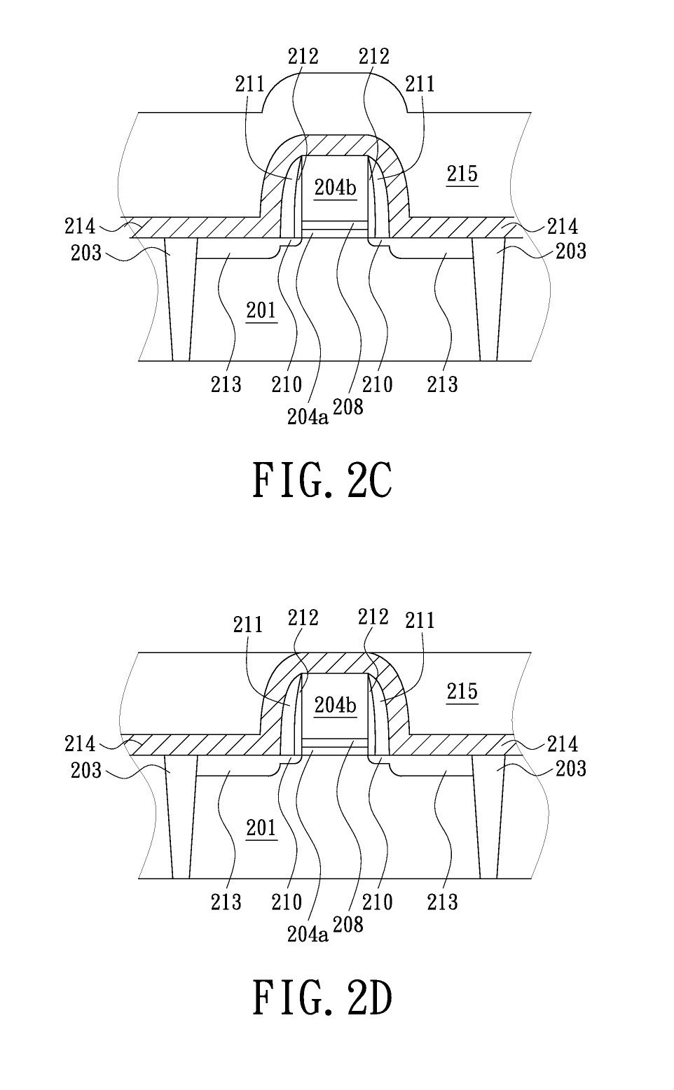

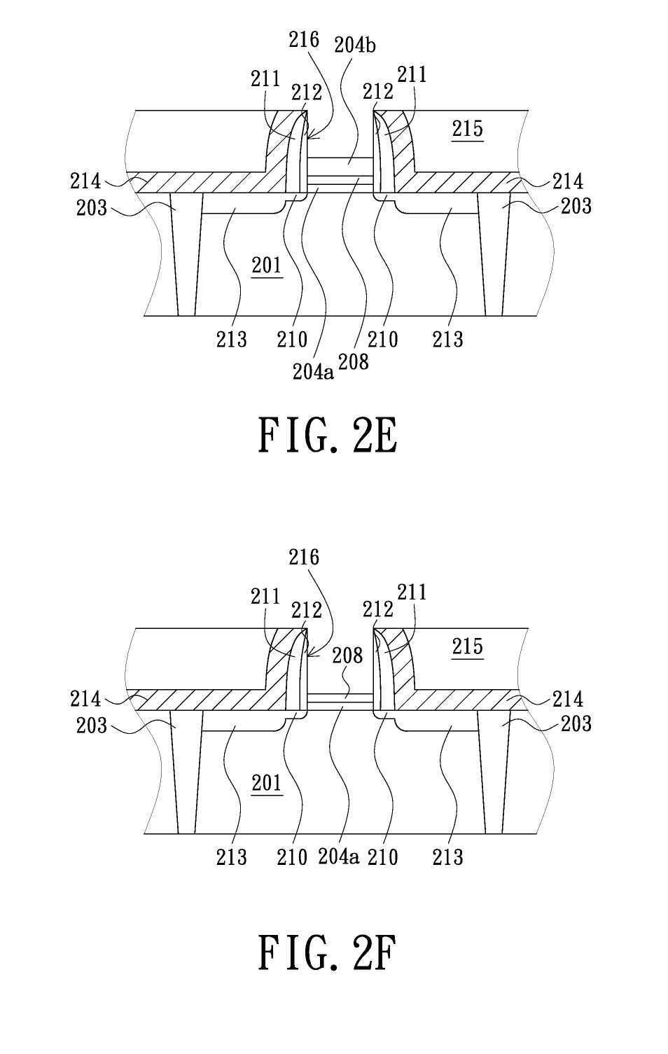

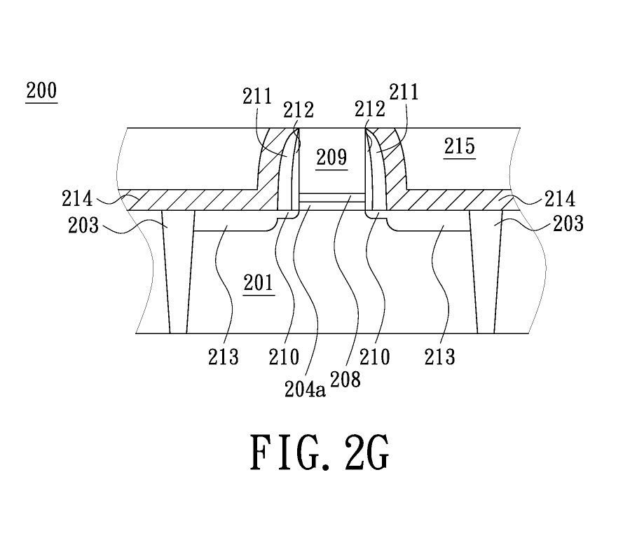

The present invention is to provide a semiconductor device with a high-k/metal gate structure. FIGS. 2A to 2G illustrate cross sectional views of the processing structures for fabricating a high-k/metal gate FET 200 in accordance with one embodiment of the present invention.

Referring to FIG. 2A, a substrate 201 including active regions 202 and isolation regions 203 is provided. In one embodiment, the substrate 201 may be a silicon substrate. In some examples of the substrate 201 may include other elementary semiconductors such as germanium and diamond or a compound semiconductor such as, silicon carbide, gallium arsenide, indium arsenide, or indium phosphide. In some embodiments of the present invention, the substrate 201 may include various doping configurations depending on design requirements (e.g., p-type substrate or n-type substrate) or epitaxial layers. In some other embodiments of the present invention, the substrate 201 may be even strained for performance enhancement, and/or may include a silicon-on-insulator (SOI) structure.

Subsequently, a dummy gate structure 204 is formed over the substrate 201. In the present embodiment, the dummy gate structure 204 comprises a gate dielectric layer 204a and a silicon layer 204b. The dummy gate structure 204 may be formed using any suitable process. In some embodiments of the present invention, the dummy gate structure 204 may be formed by steps of sequentially depositing a dielectric layer (not shown) and a poly-silicon layer (not shown) over the substrate 201, and patterning the dielectric layer and the poly-silicon layer respectively by lithographic and etching processes. In another embodiment of the present invention, the dummy gate structure 204 further comprises a hard mask layer (not shown) formed over the dummy gate structure 204. In the present embodiment, the silicon layer 204b has a thickness about 600 angstrom (Å).

However, it must be understood that the above embodiments are just examples but not limit the processing steps utilized to form the dummy gate structure 204. In some other embodiments, the dummy gate structure 204 may further comprise additional dielectric layers, conductive layers, diffusion/barrier layers, other suitable layers, and/or combinations thereof. For example, In the present embodiment, excepting the gate dielectric layer 204a and the silicon layer 204b, the dummy gate structure 204 further comprises a capping layers 208 formed on the dielectric gate dielectric layer 204a. The capping layer 208 consists of a material selected from a group of titanium nitride (TiN), tantalum nitride (TaN), tungsten nitride (WN) and the arbitrary combination thereof.

Referring to FIG. 2B, a lightly doped drain (LDD) implant process is conducted to form lightly doped source/drain (LDD) regions 210 in the substrate 201. In the present embodiment, the LDD regions 210 may be doped with p-type dopants, such as boron, n-type dopants, such as phosphorus or arsenic, and/or the combinations thereof; and the LDD regions 210 may be aligned with an outer edge of the dummy gate structure 204. In some embodiment, a sealing layer 212 may be formed on the sidewalls of the dummy gate structure 204 prior the LDD ion implantation process. The sealing layer 212 may provide protection to prevent contamination or damage to the dummy gate structure 204 during subsequent processing.

Following the formation of the LDD regions 210, a plurality of gate spacers 211 may be formed on the sidewalls of the dummy gate structure 204. The gate spacers 211 may comprise dielectric material such as silicon nitride, silicon oxide, silicon carbide, silicon oxynitride, the combinations thereof and/or other suitable materials. Then, the LDD regions 210, the dummy gate structure 204 and the spacers 209 are subjected to one or more implantation processes, such as a heavy ion implantation process, to form a source/drain region 213 in the substrate 201 and in contact with the LDD regions 210.

Referring to FIG. 2C, an etching stop layer (ESL) 214 comprising silicon nitride and/or silicon oxynitride may be formed over the substrate 201 and the dummy gate structure 20. In some embodiments of the present invention, the ESL 214 may be a single layer with a compressive strain or a stress strain. However, in some other embodiments, the ESL 214 may be a composite layer constituted by several layers with various strains. In the present embodiment, the ESL 214 is a composite layer constituted by a pad oxide layer and a CESL consisting of silicon nitride. Following the formation of the ESL 214, an ILD layer 215 is formed over the ESL 214. The ILD layer 215 may comprise a dielectric material, such as silicon oxide, silicon nitride, silicon oxynitride, spin-on glass (SOG), fluorinated silica glass (FSG), carbon doped silicon oxide (e.g., SiCOH) or the combinations thereof.

Subsequently, a CMP process stopping on the ESL 214 is conducted to remove a portion of the ILD layer 215 to expose the ESL 214 (shown in FIG. 2D). Because the selective ratio of the CMP process to remove the ILD 215 is greater than that to remove the ESL 214, thus the CMP process can be stop on the ESL 214, and rather a certain of the ESL 214 may be removed by the CMP process.

Next, an in-situ etching process is conducted to remove portions of the ESL 214 and the silicon layer 204b of the dummy gate structure 204 to form an opening 216 in the dummy gate structure 204. The in-situ etching process comprises a first dry etching step for removing a portion of the ESL 214 in order to expose the silicon layer 204b and a second dry etching step for removing the silicon layer 204b. In the embodiments of the present invention, the first dry etching step and the second dry etching step are continuously conducted in the same processing chamber or cluster tool. In the present embodiment, the first dry etching process is a CF₄/N₂ based dry etch used to remove the ESL 214; and the second dry etching step is a Cl₂ based dry etch used to partially remove a portion of the silicon layer 204b in order to remain a portion of the silicon layer 204b.

In some embodiments of the present invention, the first dry etching step has an etching selectivity of about 1:1 for removing the ESL 214 and the silicon layer 204b. In the present embodiment, the first dry etching step is operated in a CF₄/N₂ gas atmosphere with a gas flow about 20 sccm to 200 sccm and a pressure about 5 mtorr to 10 mtorr; and the second dry etching step is operated in a Cl₂ gas atmosphere with a gas flow about 45 sccm to 50 sccm and a pressure about 10 mtorr to 20 mtorr used to remove about 60% of the silicon layer 204b, such that the remaining silicon layer 204b may have a thickness less than 150 Å (shown in FIG. 2E).

In some embodiments of the present invention, following the second dry etching step, a wet chemical treatment is further conducted to remove the remaining silicon layer 204b (shown in FIG. 2F). In some embodiments of the present invention, the wet chemical treatment is a wet etching step utilizing an etchant comprising TMAH or NH₃.

Thereafter, an optional high-k gate dielectric layer and a work-function metal deposition (not shown) may be formed conformal with the sidewalls of the opening 216; and a metal material with low resistance, such as copper but not limited, is then deposited to fill the opening 216 in order to form the MG 207, and the FET 200 with a MG 207 shown in FIG. 2G is completed.

It should be appreciated that the aforementioned processes and materials for fabricating the single high-k/metal gate FET 200 are just illustrated for the purpose of clearly describing the features of the present invention, other appropriate processes and materials, however, may be used to form a complementary metal oxide semiconductor (CMOS) with a plurality of high-k/metal gate FETs.

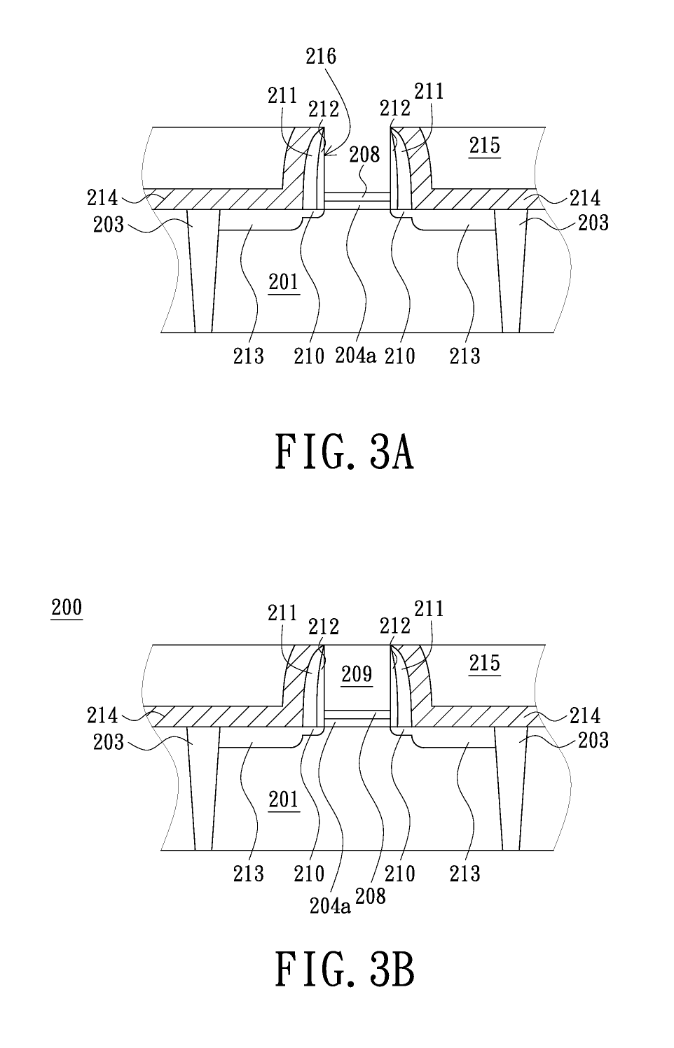

FIGS. 3A to 3B illustrate cross sectional views of the processing structures for fabricating a high-k/metal gate FET 200 in accordance with another embodiment of the present invention.

The processing steps of the present embodiment are similar to that set forth in FIGS. 2A to 2G except the in-situ etching steps for forming the opening 216, thus the description of the present embodiment is started from the process before the in-situ etching process is conducted (as shown in FIG. 2D); and the preceding processing structures which are identical to the FIGS. 2A to 2D will not be redundantly described. Like reference numbers are used to designate like elements.

After the CMP process stopping on the ESL 314 is conducted, an in-situ etching process is conducted to remove a portion of the ESL 214 and the silicon layer 204b of the dummy gate structure 204 to form an opening 216 in the dummy gate structure 204 and expose the capping layer 208 (shown in FIG. 3A). The in-situ etching process comprises a first dry etching step for removing a portion of the ESL 212 in order to expose the silicon layer 204b and a second dry etching step for removing the silicon layer 204b. In the embodiments of the present invention, the first dry etching step and the second dry etching step are continuously conducted in the same processing chamber or cluster tool. In the present embodiment, the first dry etching process is a CF₄/N₂ based dry etch used to remove the ESL 214; and the second dry etching step is an HBr based dry etch used to remove a portion of the silicon layer 204b in order to expose the capping layer 308.

In some embodiments of the present invention, the first dry etching step has an etching selectivity of 1:1 for removing the ESL 214 and the silicon layer 204b. In the present embodiment, the first dry etching step is operated in a CF₄/N₂ gas atmosphere with a gas flow about 20 sccm to 200 sccm and a pressure about 5 mtorr to 10 mtorr, and the second dry etching step may have an etching rate for removing the silicon layer 204b greater 10 times than that for removing the capping layer 208. Preferably, the second dry etching step may be operated in a HBr gas atmosphere with a gas flow about 200 sccm to 300 sccm and a pressure about 5 mtorr to 10 mtorr.

In some embodiments of the present invention, following the second dry etching step, a wet chemical treatment is further conducted to remove the polymer residues remaining on the sidewalls of the opening 216 and the capping layer 208. In some embodiments of the present invention, the wet chemical treatment is a residue-cleaning step utilizing a reagent comprising TMAH.

Thereafter, an optional high-k gate dielectric layer and a work-function metal deposition (not shown) may be formed conformal with the sidewalls of the opening 216; and a metal material with low resistance, such as copper but not limited, is then deposited to fill the opening 216 to form a MG 207, and the FET 200 with the MG 207 as shown in FIG. 3B is completed.

It should be appreciated that the aforementioned processing structures and materials are just illustrated for fabricating the single high-k/metal gate FET 200 for the purpose of clearly describing the features of the present invention, other appropriate processes and materials, however, may be used to form a complementary metal oxide semiconductor (CMOS) with a plurality of high-k/metal gate FETs with different electrical conductivity.

In accordance with the aforementioned embodiments of the present invention, a method for fabricating a semiconductor device with a MG structure is provided, wherein a dummy poly gate previously formed on a semiconductor substrate is replaced by the metal gate structure. In stead of performing a conventional dummy poly gate removing procedure which includes a CMP process for removing a ESL covered on the dummy poly gate structure and a subsequent chemical wet etching process for removing a silicon layer of the dummy poly gate, an in-situ etching process is performed to accomplish the work done by the conventional dummy poly gate removing procedure at a time in the same processing chamber or cluster tool. Besides, in comparison with the traditional chemical wet etching process, the present in-situ etching process has lower etching selectivity for removing the silicon nitride and the silicon, thus the polymer residue generated in the etching process can be significantly reduced, so that the total account of the defect semiconductor device can be reduced. Therefore, the drawbacks and problems encountered from the prior art can be solved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures. Specifically and by way of example, words of inclusion are to be interpreted as unexhausted in considering the scope of the invention, fore example, the term of “about” should be construed by any skilled in the art to cover the scope +/−10% of a certain number which is disclosed

Further, a description of a technology in the “Background” or “Description of Related Art” is not be construed as an admission that technology is prior art to the present application. Neither is the “Summary of the Invention” to be considered as a characterization of the invention(s) set forth in the claims to this application.

What is claimed is:

1. a method for fabricating a semiconductor device comprising:
providing a semiconductor structure comprising a substrate, a dummy gate structure having a dielectric layer disposed over the substrate and a silicon layer disposed over the dielectric layer, and an etching stop layer (ESL) and an inter-layer dielectric (ILD) layer both of which are sequentially disposed over the substrate and the dummy gate structure;
performing a chemical mechanical polishing (CMP) to planrizing the ILD layer and expose the ESL;
conducting an in-situ etching process to remove portions of the ESL and the silicon layer to form an opening in the dummy gate structure; and
filling a metal material into the opening.

2. The method for fabricating the semiconductor device according to claim 1, wherein the ESL comprises silicon nitride or silicon oxynitride.

3. The method for fabricating the semiconductor device according to claim 1, wherein the in-situ etching process comprises:
a first dry etching step for removing a portion of the ESL in order to expose the silicon layer; and
a second dry etching step for removing the silicon layer.

4. The method for fabricating the semiconductor device according to claim 3, further comprising a wet chemical treatment for removing the remaining silicon layer after the second dry etching step is conducted.

5. The method for fabricating the semiconductor device according to claim 4, wherein the wet chemical treatment is a wet etching step utilizing an etchant comprising tetramethylammonium hydroxide (TMAH) or ammonia (NH₃).

6. The method for fabricating the semiconductor device according to claim 4, wherein the wet chemical treatment is a cleaning step utilizing a reagent comprising TMAH.

7. The method for fabricating the semiconductor device according to claim 3, wherein the first dry etching step comprises a carbon fluoride (CF4)/nitrogen (N2) based dry etch.

8. The method for fabricating the semiconductor device according to claim 7, wherein the first dry etching step has an etching selectivity of 1:1 for removing the ESL and the silicon layer.

9. The method for fabricating the semiconductor device according to claim 8, wherein the second dry etching step is a chlorine (Cl₂) based dry etching.

10. The method for fabricating the semiconductor device according to claim 7, wherein the second dry etching step partially removes the silicon layer so as to remain a portion of the silicon layer.

11. The method for fabricating the semiconductor device according to claim 10, wherein the second dry etching step removes about 60% of the silicon layer.

12. The method for fabricating the semiconductor device according to claim 11, further comprising forming a capping layer on the dielectric layer prior the silicon layer is formed, and the second dry etching step has an etching rate for removing the silicon layer greater 10 times than that for removing the capping layer.

13. The method for fabricating the semiconductor device according to claim 12, wherein the capping layer consists of material selected from a group of titanium nitride (TiN), tantalum nitride (TaN), tungsten nitride (WN) and the arbitrary combination thereof.

14. The method for fabricating the semiconductor device according to claim 7, wherein the second dry etching step is a hydrogen bromide (HBr) based dry etching.
